(19) United States
(12) Patent Application Publication
(10) Pub. No.: US 2020/0205302 A1
(43) Pub. Date: Jun. 25, 2020

(54) DISPLAY DEVICE

(71) Applicant: SKIDATA AG, Grödig/Salzburg (AT)

(72) Inventors: Erich KRANZINGER, Grödig/Salzburg (AT); Simon REICHARTZEDER, Grödig/Salzburg (AT)

(21) Appl. No.: 16/720,051

(22) Filed: Dec. 19, 2019

(30) Foreign Application Priority Data
Dec. 24, 2018 (EP) 18215836.0

(51) Int. Cl. H05K 5/00; F16F 1/02; B29C 73/24

(52) U.S. Cl. CPC H05K 5/0017; B29L 2031/3481; B29C 73/24; F16F 1/027

(57) ABSTRACT

A display device comprising a display (2), with electronic components, and a transparent front pane (1) arranged in front of the display. The display (2) is connected to a support (3) and is adjustable mounted along an axis extending perpendicularly to the planes defined by the surfaces of the front pane (1) and the display (2) between a minimum value distance between the display (2) and the front pane (1) and a maximum value for the distance between the display (2) and the front pane (1). The display device has a mechanism (4, 15) by which the distance between the display (2) and the front pane (1) can be dynamically modified as a function of the temperature. When the temperature falls below a lower threshold, the distance assumes the minimum value, and, when the temperature is above the lower threshold, the distance is increased up to an upper threshold.

This application claims priority from European patent application serial no. 18215836.0 filed Dec. 24, 2018.

### FIELD OF THE INVENTION

The present invention relates to a display device, in particular for equipment set up outdoors, for example for access control devices, automated vending and payment stations or digital signage equipment.

### BACKGROUND OF THE INVENTION

Display devices and equipment comprising display devices such as, for example, access control devices, automated vending and payment stations as well as digital signage equipment, are often set up outdoors, whereby they are exposed to various weather conditions.

In the event of high temperatures or direct solar irradiation, the quality of such display devices can be impaired in a disadvantageous manner.

Furthermore, in the event of high outdoor temperatures or direct solar irradiation, the display, which contains electronic components, of the display devices can be damaged.

The provision of display devices that are set up outdoors with cool air by means of a fan or suitable air-cooling devices is known from the prior art. The display of the display devices, however, cannot be cooled evenly or completely in this case.

Also known from the prior art is the combination of the front pane of the display of display devices with a further pane made of a transparent material so that the further pane made of a transparent material, the front pane and the glued-together edges of the front pane and the further pane made of a transparent material form a cuboid cavity, which can be completely filled with a transparent fluid that is circulated by means of a closed fluid circuit in order to ensure a predetermined temperature of the fluid present in the cavity. This solution, however, has proven very cost-intensive. Furthermore, a considerable amount of maintenance is required.

### SUMMARY OF THE INVENTION

The basic object of the present invention is to provide a display device that can be operated in the event of high temperatures and direct solar irradiation without the risk of temperature-related damage.

This object is achieved by means of the features of the independent claim(s). Further embodiments and advantages according to the invention are indicated in the dependent claims.

A display device is thus proposed that comprises a display configured in accordance with the prior art with electronic components, a front pane made of a transparent material being arranged in front of and parallel to the side of the display that, in the mounted state, faces the observer, wherein the display is connected to a support and is arranged and mounted in an axially adjustable manner along an axis extending perpendicularly to the planes defined by the surfaces of the front pane and of the display, between a first point corresponding to a minimum value for the distance between the display and the front pane and a second point corresponding to a maximum value for the distance between the display and the front pane, wherein the display device has means by means of which the distance between the display and the front pane made of transparent material is dynamically modifiable as a function of the temperature.

The mounting of the support of the display can occur, for example, by means of sliding pins, formed by a support of the front pane or a fixed structural component of the display device or connected to the same, and sliding sleeves, formed by the support of the display or connected to the same, in which the sliding pins are guided. The sliding pins and the corresponding sliding sleeves are provided here on at least two opposite sides of the support of the front pane or of the fixed structural component and of the support of the display, wherein the amount depends on the structural circumstances.

According to further embodiments, the mounting can occur via rolling-element bearings or rubber/plastic plain bearings. The mounting can, moreover, occur via a spindle which engages in a threaded bushing connected to the support of the display and is attached to the support of the front pane or to a fixed structural component of the display device via an axially fixed, yet radially freely rotatable bearing; vibrations are avoided to a great extent by such an embodiment.

In the event of low temperatures, i.e. temperatures that fall below a low threshold value, the distance assumes a minimum value in accordance with the invention that is preferably in the order of half a millimetre, which results in an optimal readability and operability, in particular in the case of a touch-sensitive display device.

According to the invention, in the event of temperatures above the low threshold value, the distance between the display and the front pane is increased as a function of the temperature up to the predefined maximum value, which corresponds to an upper temperature threshold and which is preferably in the order of a centimetre. In the event of sinking temperatures, the distance between the display and the front pane is reduced in the range between the upper and lower temperature thresholds to the minimum value.

In accordance with the invention, the means for modifying the distance between the display and the front pane can be bimetallic elements, which are connected or operatively connected to the front pane, or a further structural component arranged in a fixed manner that can be connected to the front pane, and to the support of the display, which are arranged so that their expansion in the event of an increase in temperature causes an increase in the distance between the display and the front pane, wherein, in the event of a cooling, the contraction of the bimetallic elements causes a reduction of the distance between the display and the front pane. According to further embodiments, the contraction process of the bimetallic elements or the axial adjustment of the display in the event of a fall in temperature can be supported by resetting spring elements.

According to an embodiment of the invention, the means for modifying the distance between the display and the front pane are bimetallic springs, which are respectively arranged around a profile preferably configured in the shape of a cylinder extending perpendicularly to the planes defined by the surfaces of the front pane and of the display, the end of the profile facing the front pane being arranged in a fixed manner either on the support of the front pane or on a further structural component of the display device, wherein the support of the display has on at least one side respectively at least two sliding members, which are respectively guided in an adjustable manner along a profile and respectively arranged between the bimetallic spring and a resetting spring, wherein each bimetallic spring is respectively arranged between the sliding member and the end of the profile facing the front pane and each resetting spring is respectively arranged between the sliding member and the end of the profile facing away from the front pane. According to the invention the support can have on at least two opposite sides respectively at least two sliding members, which are each guided along a profile in an adjustable manner.

The increasing of the distance between the display and the front pane occurs here by means of an axial adjustment of the support due to the expansion of the bimetallic springs as a function of the temperature against the force of the respective resetting springs. The resetting springs are designed so that they facilitate an increasing of the distance between the front pane and the display up to the predetermined maximum value, wherein the axial position of the sliding members is defined as a function of the temperature by means of the balance of forces between the respective bimetallic spring and resetting spring. Moreover, the bimetallic springs are designed so that the distance between the front pane and the display does not fall below the predetermined minimum value,

Within the framework of a further embodiment, the bimetallic springs are respectively arranged around a sliding pin configured in the shape of a cylinder extending perpendicularly to the planes defined by the surfaces of the front pane and of the display, the end of the pin facing the front pane being connected either to a support of the front pane or to a further structural component of the display device, wherein the support of the display has on at least two opposite sides respectively at least one sliding sleeve, into which a sliding pin is respectively guided, wherein the bimetallic springs press against the support of the front pane, or against a further structural component, and against the support of the display and, in the event of an increase in temperature, move the support of the display against the force of a resetting spring in a direction away from the front pane.

According to a further embodiment, the means for modifying the distance between the display and the front pane comprise at least one bimetallic strip connected at its ends to the front pane or to a structural component connected to the front pane, said bimetallic strip abutting the support of the display or being connected to the same, bulging in the event of an increase in temperature in the direction of the display and moving the same against the force of the at least one resetting spring axially in a direction away from the front pane. In the event of a fall in temperature, the contraction process of the at least one bimetallic strip is supported by means of the at least one resetting spring, wherein the distance between the display and the front pane is reduced in accordance with the temperature. The at least one resetting spring is designed so as to enable an increasing of the distance between the front pane and the display up to the predetermined maximum value, wherein the axial position of the display is defined as a function of the temperature by the balance of forces between the bimetallic strips and the at least one resetting spring. The bimetallic strips are designed so that the distance between the front pane and the display does not fail below the predetermined minimum value. The bimetallic strips are preferably connected by their side facing the display to the support of the display in an interlocking or force-locked manner.

According to a further embodiment, the means for modifying the distance between the display and the front pane comprise at least one arched bimetallic strip, whose one end is connected to the front pane or a structural component connected to the front pane and whose other end is connected to the support of the display, which expands in the event of an increase in temperature and moves the display axially in a direction away from the front pane. In the event of a fall in temperature, the distance between the display and the front pane is reduced in accordance with the temperature by means of the contraction process of the bimetallic strip. The contraction process of the bimetallic strip can optionally be supported by means of at least one resetting spring element.

Within the framework of a further embodiment in accordance with the invention, the means for modifying the distance between the front pane and the display as a function of the temperature are configured as at least one electric, pneumatic, hydraulic or electromagnetic actuator, which is controlled as a function of the temperature determined by at least one sensor by a control unit in order to set the predetermined distance between the display and the front pane as a function of the temperature. The distance between the front pane and the display as a function of the temperature can be saved as a response curve stored in a control unit.

Within the framework of an embodiment of the invention, a proximity sensor can additionally be provided, wherein, if the presence of a person in front of the display device is detected by means of the sensor and the distance between the display and the front pane does not correspond to the minimum value, the at least one actuator is activated in order to reduce the distance between the front pane and the display to the minimum value so that an optimal readability and operability is ensured during the presence of the person, high temperatures notwithstanding.

### BRIEF DESCRIPTION OF THE DRAWINGS

The invention will be explained in greater detail in the following by means of the attached illustrative figures. Like references designate like structural components. The general structure of display devices is well known to those skilled in the art so that, in the following, the features that are significant for the present invention are illustrated and described in detail. For example, the housing and the electronic components necessary for the operation of the display are not illustrated. The figures show:

FIG. 1: A schematic sectional view of a part of a display device configured in accordance with the invention, in which the distance between the front pane and the display corresponds to the minimum value;

FIG. 2: A schematic sectional view of a part of the display device shown in FIG. 1, in which the distance between the front pane and the display corresponds to the maximum value;

FIG. 3: A schematic front view of the front pane of an embodiment of a display device configured in accordance with the invention;

FIG. 4: A schematic perspective view of the display device shown in FIG. 3;

FIG. 5: A section along the line A-A indicated in FIG. 3;

FIG. 6: A section along the line B-B indicated in FIG. 3;

FIG. 7: A schematic perspective view of a further embodiment of a display device in accordance with the invention;

FIG. 8: A schematic rear view of the display device shown in FIG. 7 (right part) and a section along the line A-A (left part);

FIG. 9: A schematic perspective view of a further embodiment of a display device in accordance with the invention;

FIG. 10: A schematic rear view of the display device shown in FIG. 9;

FIG. 11: A section along the line A-A indicated in FIG. 10;

FIG. 12: A schematic front view of the front pane of an embodiment of a display device in accordance with the invention;

FIG. 13: A section along the line B-B indicated in FIG. 12;

FIG. 14: A section along the line C-C indicated in FIG. 12;

FIG. 15: A section along the line A-A indicated in FIG. 12;

FIG. 16: A sectional view along the line D-D indicated in FIG. 15;

FIG. 17: A sectional view of a further embodiment of the invention for illustrating a possible arrangement of an actuator; and

FIG. 18: A schematic perspective view of a further embodiment of a display device according to the invention in which at least one actuator is provided.

### DETAILED DESCRIPTION OF THE PREFERRED EMBODIMENTS

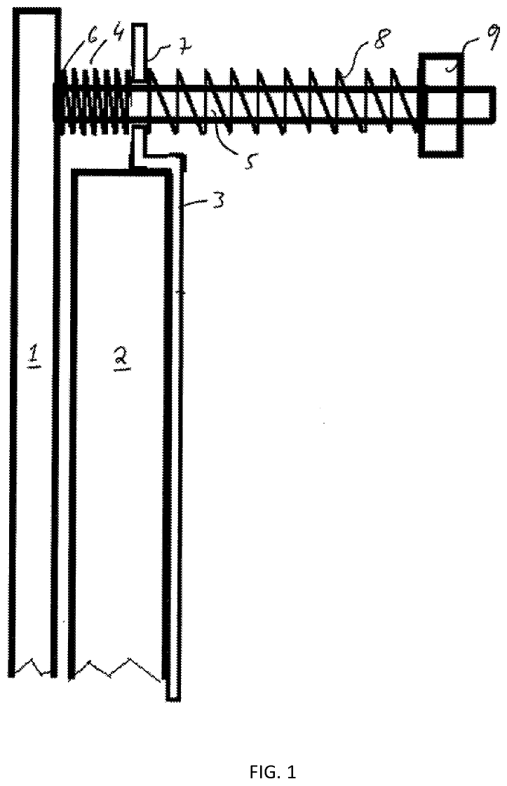

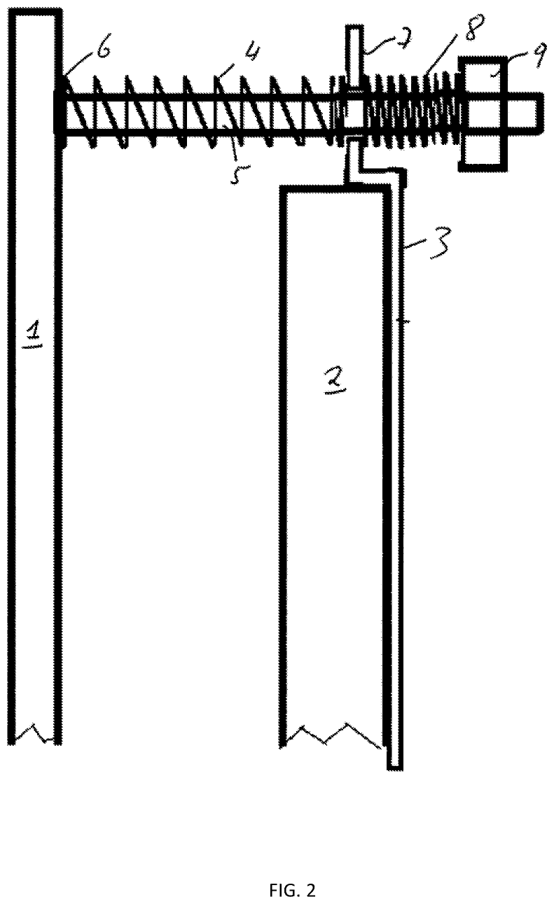

In FIGS. 1 and 2, the front pane is designated with 1 and the display of the display device is designated with 2, while the support of the display 2 is designated with 3. The upper side of the display device is illustrated here; the lower side is structured analogously to the upper side.

In the illustrated example, the means for modifying the distance between the display 2 and the front pane 1 are bimetallic springs 4, which are respectively arranged around a profile 5 configured in the shape of a cylinder extending perpendicularly to the planes defined by the surfaces of the front pane 1 and the display 2, the end of the profile facing the front pane being arranged on a support $ of the front pane 1.

With reference to FIGS. 1 and 2, the support 3 of the display 2 has on its upper and its lower side respectively two sliding members 7 (only one sliding member is illustrated in FIGS. 1 and 2), which are respectively guided in an adjustable manner along a profile 5 and which are arranged between the respective bimetallic spring 4 and resetting spring 8, wherein each bimetallic spring 4 is respectively arranged between the sliding member 7 and the end of the profile 5 facing the front pane 1 and each resetting spring 8 is respectively arranged between the sliding member 7 and the end of the profile 5 facing away from the front pane and presses against a stop 9.

The increasing of the distance between the display 2 and the front pane 1 occurs here by means of an axial adjustment of the support 3 attached to the display 2 due to the expansion of the bimetallic springs 4 as a function of the temperature against the force of the respective resetting springs 8. The resetting springs 8 are designed so that they facilitate an increasing of the distance between the front pane 1 and the display 2 up to the predetermined maximum value, wherein the axial position of the sliding members 7 is defined as a function of the temperature by the balance of forces between the respective bimetallic spring 4 and resetting spring 8, wherein the bimetallic springs 4 are designed to that the distance between the front pane 1 and the display 2 does not fall below the predetermined minimum value for said distance. The friction coefficient between the profiles 5 and the sliding members 7 is as low as possible.

In FIG. 1, the display device is shown in a state in which the distance between the front pane 1 and the display 2 corresponds to the minimum value, while FIG. 2 illustrates the display device in a state in which the distance between the front pane 1 and the display 2 corresponds to the maximum value.

In the embodiment according to FIGS. 1 and 2, the profiles 5 and the sliding members 7 are provided on the upper and lower side of the display; within the framework of further embodiments, the profiles 5 and the sliding members 7 can be provided on the right and left side of the display.

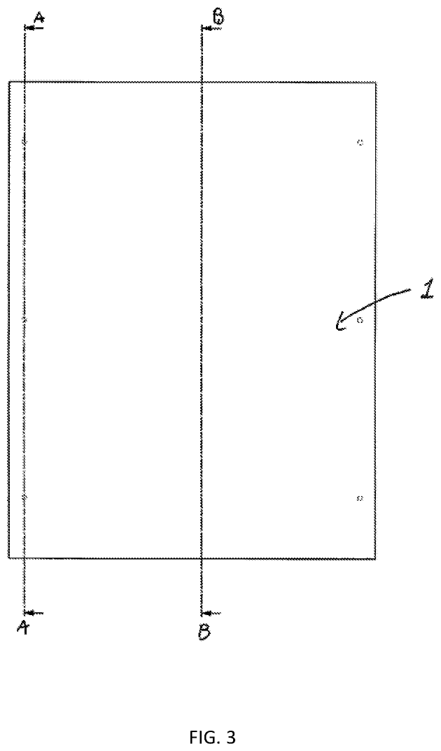

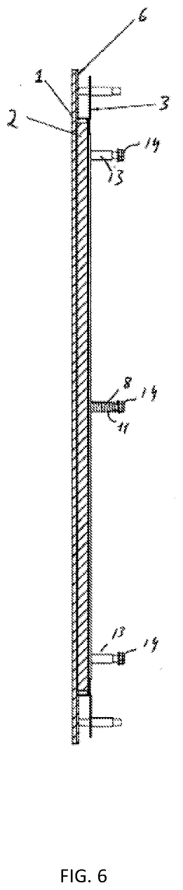

According to a further embodiment of the invention and with reference to FIGS. 3, 4, 5 and 6, the bimetallic springs 4 acting as means for modifying the distance between the front pane and the display as a function of the temperature are respectively arranged around a sliding pin 10 configured in the shape of a cylinder extending perpendicularly to the planes defined by the surfaces of the front pane 1 and of the display 2, the end of the pin facing the front pane 1 being connected to the support 6 of the front pane 1. In this case, the support 3 of the display 2 has on at least two opposite sides respectively at least one sliding sleeve 11, into which a pin 10 is respectively guided. According to further embodiments, further sliding sleeves can be provided, into which a pin is respectively guided, around which a bimetallic spring is arranged. In the illustrated example, respectively on two opposite sides of the supports 3, 6 of the display 2 and of the front pane 1, a sliding pin 10 and a sliding sleeve 11 are respectively provided.

In the illustrated example, the mounting of the support of the display occurs by means of sliding pins 12, which are formed by the support 6 of the front pane 1 or are connected to the same, and sliding sleeves 13 formed by the support 3 of the display 2 or connected to the same, in which the sliding pins 12 are guided. This mounting is independent of the type of means for modifying the distance between the front pane and the display as a function of the temperature and can, for example, also be provided in the example configuration shown in FIGS. 1 and 2 or in embodiments in which the means for modifying the distance between the front pane and the display as a function of the temperature are configured as an electric, pneumatic, hydraulic or electromagnetic actuator.

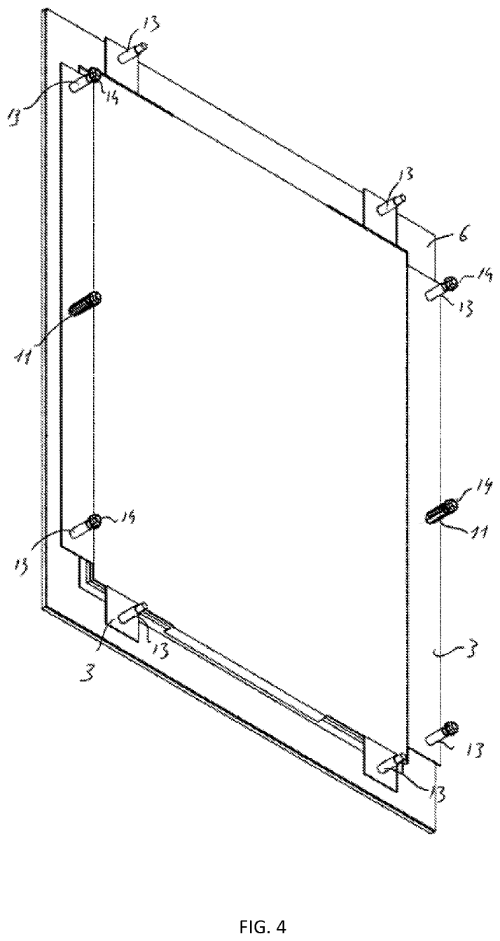

In FIG. 3, the front side of the front pane 1 of the display device is illustrated. In the perspective view shown in FIG. 4, 5 designates the support of the front pane, 3 the support of the display, 13 the sleeves in which sliding pins are guided for mounting, and 11 the sleeves into which a pin is respectively guided, around which pin a bimetallic spring 4 is arranged.

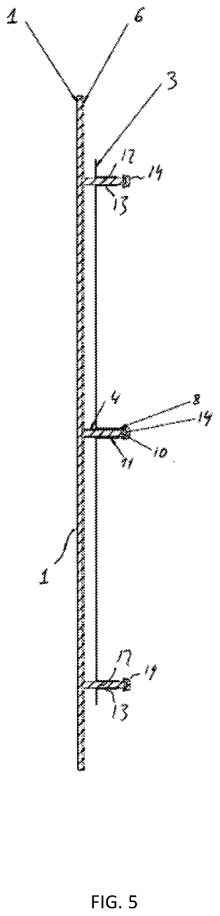

It is apparent from FIG. 5, which illustrates a section along the line A-A indicated in FIG. 3, that the bimetallic springs 4 press against the support 6 of the front pane 1 and against the support 3 of the display 2 so that, in the event of an increase in temperature, the support 3 of the display 2 is moved against the force of the resetting spring 8 in a direction away from the front pane 1. In FIGS. 4, 5 and 6, end caps for the sleeves 11, 13 are provided with the reference 14,

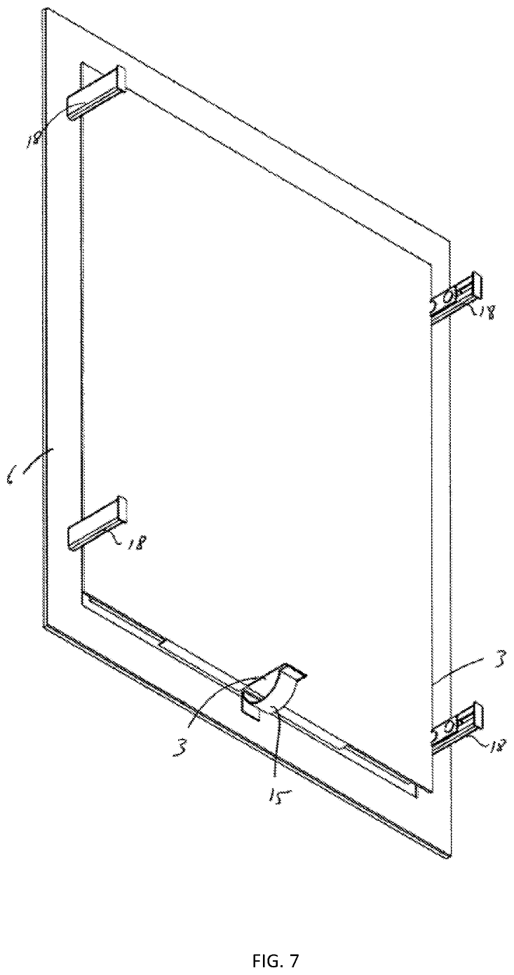

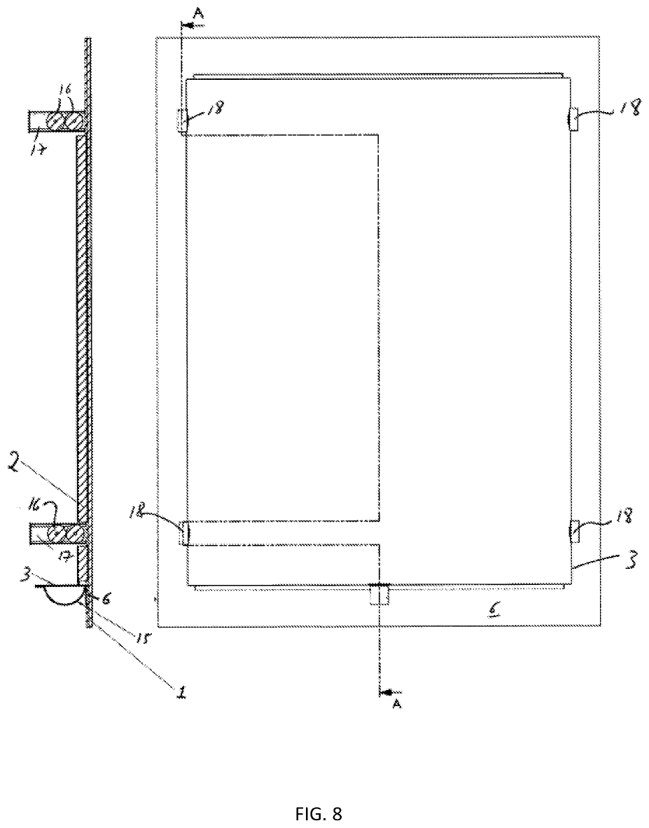

The object of the FIGS. 7 and 8 is a further embodiment of the invention in which, as means for modifying the distance between the display 2 and the front pane 1, an arched bimetallic strip 15 is provided, one end of which is connected to the support 6 of the front pane 1, for example glued or welded, and the other end of which is connected to the support 3 of the display 2, which expands in the event of an increase in temperature and moves the display 2 axially in a direction away from the front pane 1. In the event of a fall in temperature, the distance between the display and the front pane is reduced in accordance with the temperature due to the contraction process of the bimetallic strip 15, wherein the contraction process of the bimetallic strip can optionally be supported by means of at least one resetting spring element. Within the framework of further embodiments., further bimetallic strips can be provided.

In the example shown in FIGS. 7 and 8, the mounting of the support 3 of the display 2 occurs by means of plastic or rubber rollers 16 mounted in a rotatable manner on the support 3 of the display, said rollers 16 being guided in a guide rail 17 connected to the support 6 of the front pane 1 and respectively forming a mounting unit 18. At least two mounting units are provided here on at least two opposite sides of the display 2 and front pane 1. This mounting is independent of the type of means for modifying the distance between the front pane and the display as a function of the temperature and can, for example, also be provided in the example configurations shown in FIGS. 1, 2, 3, 4, 5 and 6 or in embodiments in which the means for modifying the distance between the front pane and the display as a function of the temperature are configured as at least one electric, pneumatic, hydraulic or electromagnetic actuator.

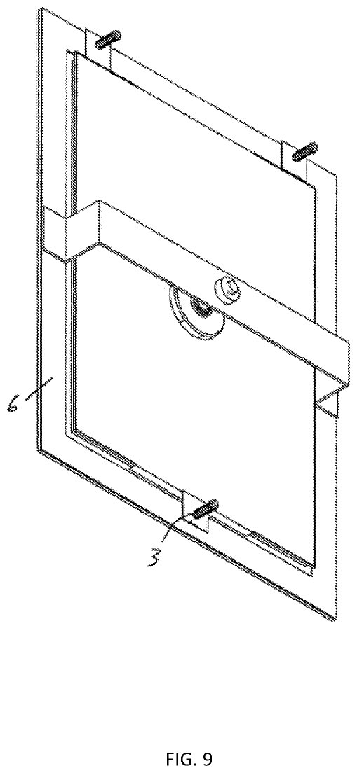

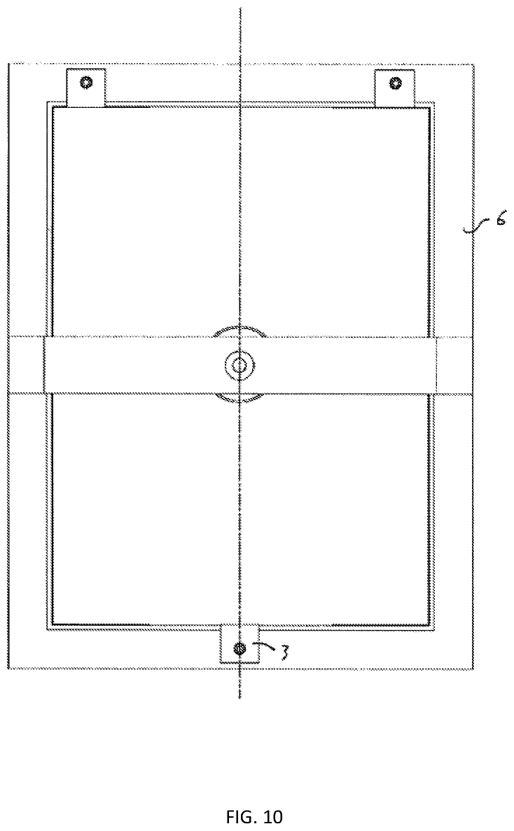

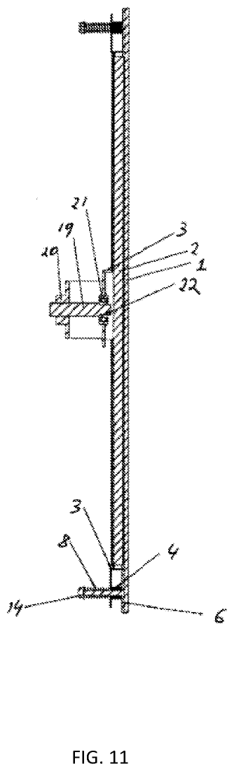

The object of the FIGS. 9, 10 and 11 is a further embodiment of the invention in which, as means for modifying the distance between the front pane and the display as a function of the temperature and analogously to the example configuration shown in FIGS. 3, 4 and 5, bimetallic springs 4 are provided, which are respectively arranged around a sliding pin 10 configured in the shape of a cylinder extending perpendicularly to the planes defined by the surfaces of the front pane 1 and of the display 2, the end of the pin facing the front pane 1 being connected to the support 6 of the front pane 1, wherein the support 3 of the display 2 has on at least two opposite sides respectively at least one sliding sleeve 11, into which a pin 10 is respectively guided. In the illustrated example, two sliding pins 10 and two sliding sleeves 11 are provided on the upper side of the supports 3, 6 of the display 2 and of the front pane 1, while, on the lower side, one sliding pin 10 and one sliding sleeve 11 are provided. The bimetallic springs 4 press against the support 6 of the front pane 1 and against the support 3 of the display 2 so that, in the event of an increase in temperature, the support 3 of the display 2 is moved against the force of the respective resetting springs 8 in a direction away from the front pane 1.

The mounting of the support 3 of the display 2 of the display device occurs in the illustrated example via a spindle 19, which engages in a threaded bushing 20 connected to the support 3 of the display 2 and is attached on the support 6 of the front pane 1 via an axially fixed, yet radially freely rotatable ball bearing 21 by means of, for example, a compression connection 22. This mounting is independent of the type of means for modifying the distance between the front pane and the display as a function of the temperature and can, for example, also be provided in the example configurations shown in FIGS. 1, 2, 3, 4, 5, 6, 7 and 8 or in embodiments in which the means for modifying the distance between the front pane and the display as a function of the temperature are configured as at least one electric, pneumatic, hydraulic or electromagnetic actuator.

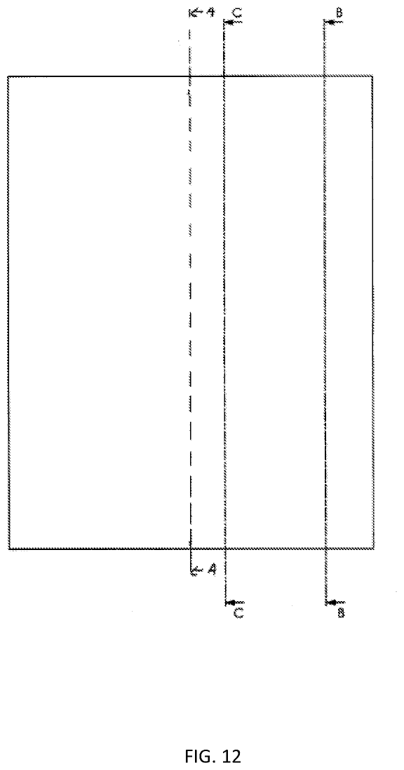

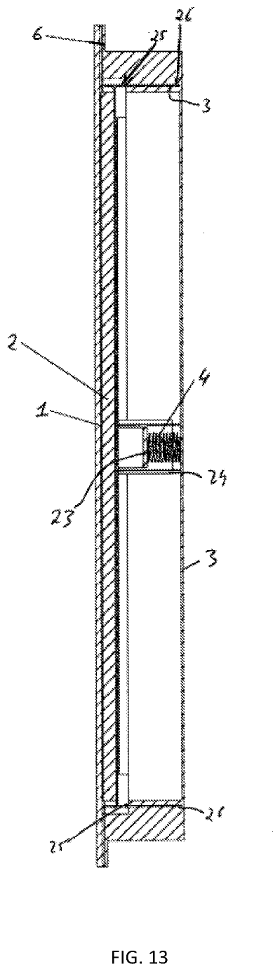

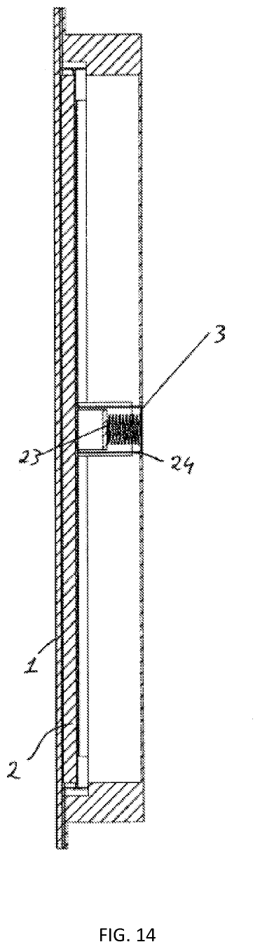

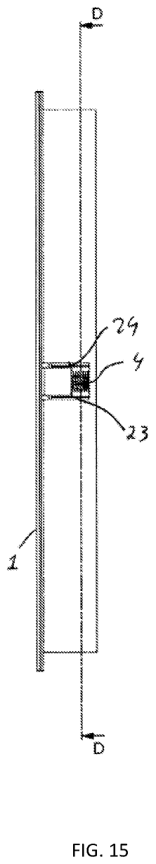

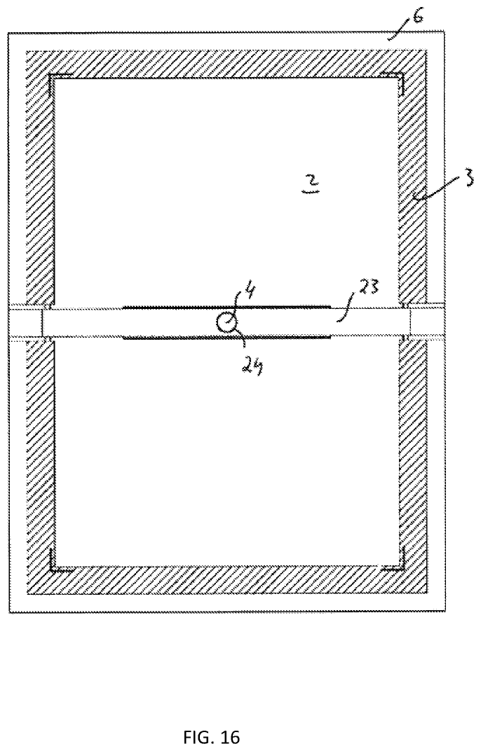

The object of the FIGS. 12, 13, 14, 15 and 16 is an embodiment of the invention in which, as means for modifying the distance between the display 2 and the front pane 1, a bimetallic spring 4 is provided centrally on the back of the display 2, the bimetallic spring 4 being connected to the support 3 of the display 2 or to a structural component connected to the support by its end facing away from the display, while the other end facing the display 2 is connected to a structural component arranged in a fixed manner in the display device, which is arranged between the display 2 and the support 3 of the display or the structural component connected to the support, so that, in the event of an increase in temperature, the distance between the display 2 and the front pane 1 is increased. As shown in FIGS. 13 and 14, the support 3 of the display 2 is configured so that a structural space is provided between the side of the display 2 facing the front pane 1 and the support 3, in which spate a structural component 23 arranged in fixed manner is arranged, to which the end of the bimetallic spring 4 facing the display 2 is connected. The bimetallic spring is guided in a sleeve 24 in the illustrated example. Instead of the illustrated bimetallic spring 4, an arched bimetallic spring can also be used. Optionally, at least one resetting spring element can be used for supporting the contraction process of the bimetallic spring 4 or of the bimetallic strip.

In the embodiment of the display device shown in FIGS. 12 16, the mounting of the support 3 of the display 2 occurs by means of springs 25 provided in the support 3 of the display 2, the springs 25 engaging in grooves 26 provided in the support 6 of the front pane 1. This mounting is independent of the type of means for modifying the distance between the front pane 1 and the display 2 as a function of the temperature and can, for example, also he provided in all of the illustrated example configurations or in embodiments in which the means for modifying the distance between the front pane and the display as a function of the temperature are configured as at least one electric, pneumatic, hydraulic or electromagnetic actuator.

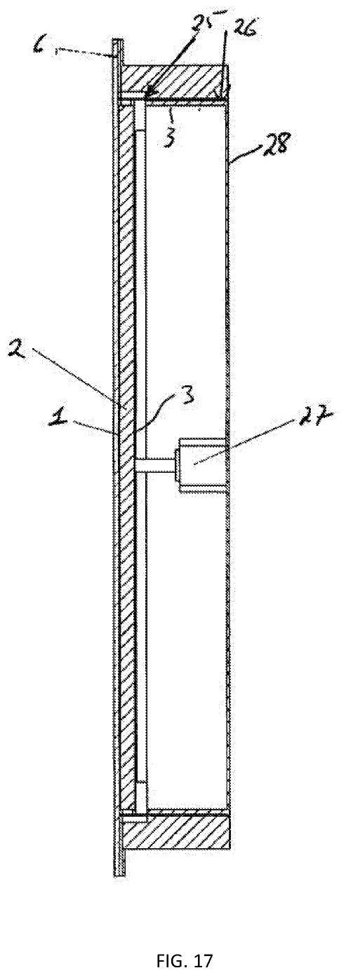

With respect to this mounting, the example configuration shown in FIG. 17 corresponds to the example configuration shown in FIGS. 12, 13, 14, 15 and 16, wherein, instead of the bimetallic spring provided centrally on the back of the display 2, a linear actuator 27 arranged on a fixed structural component 28 is provided, which is connected to the back of the display 2 or to the support 3 of the display 2 so that the display 3 can be moved axially.

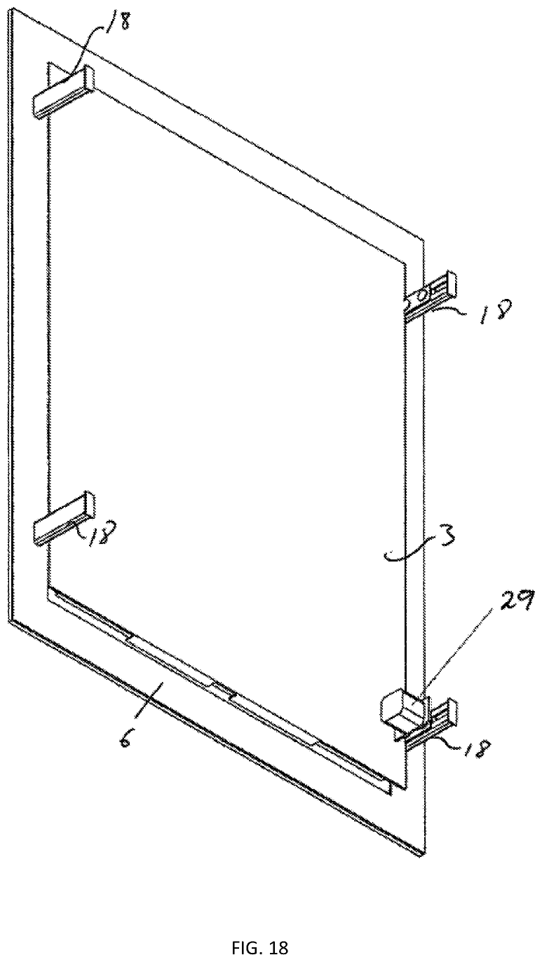

Moreover, the example configuration illustrated in FIG. 18 differs from the example configuration shown in FIGS. 7 and 8 in that the arched bimetallic strip is omitted, while an actuator 29 is provided, which is connected to the support 3 of the display 2 and which drives rollers 16 of a mounting unit 18, said rollers 16 being guided in a guide rail 17. The rollers 16 here can also be configured as gearwheels, which engage in corresponding toothed structures of the guide rail 17. In the illustrated example, an actuator 29 is provided, which is matched with a mounting unit 18. In the framework of further embodiments, a further actuator can respectively be matched with at least one further mounting unit 18.

According to the invention, the at least one bimetallic element can be replaced in each of the illustrated embodiments by an actuator, which is attached on one side to the display 2 or the support 3 of the display 2 and on the other side to a structural component arranged in a fixed manner.

The different mounting concepts can be combined in any way with the different embodiments of the means for modifying the distance between the front pane 1 and the display 2 as a function of the temperature.

When resetting springs are provided, these are designed so that they enable an increasing of the distance between the front pane and the display up to the predetermined maximum value, wherein the axial position of the display is defined as a function of the temperature by the balance of forces between the bimetallic elements and the at least one resetting spring element. The bimetallic elements are designed so that the distance between the front pane and the display does not fall below the predetermined minimum value.

1. A display device[, ] comprising:
a display (2) with electronic components,
a front pane (1) made of a transparent material being arranged in its mounted state in front of a side of the display that faces an observer and parallel to the display,
wherein the display (2) is connected to a support (3) and is arranged and mounted in an axially adjustable manner along an axis extending perpendicularly to planes defined by surfaces of the front pane (1) and of the display (2), between a first point corresponding to a minimum value for a distance a between the display (2) and the front pane (1) and a second point corresponding to a maximum value for the distance between the display (2) and the front pane (1), the display device has means (4, 15) for modifying the distance between the display (2) and the front pane (1) can be modified in a dynamic manner as a function of the temperature, and, in an event of the temperature falling below a lower threshold, the distance assumes the minimum value and, in the event of the temperature[s] above the lower threshold, the distance between the display (2) and the front pane (1) is increased as a function of the temperature up to the predefined maximum value corresponding to an upper threshold.

2. The display device according to claim 1, wherein the means for modifying the distance between the display (2) and the front pane (1) are bimetallic elements (4, 15), which are connected or operatively connected to the front pane (1) or a further structural component arranged in a fixed manner, which can be connected to the front pane (1), and to the support (3) of the display (2), which are arranged so that expansion of the bimetallic elements (4, 15) in the event of an increase in the temperature causes an increase in the distance between the display (2) and the front pane (1), and, in the event of a cooling, contraction of the bimetallic elements (4, 15) causes a reduction of the distance between the display (2) and the front pane (1), and the contraction process of the bimetallic elements or the axial adjustment of the display (2), in the event of a fall in temperature, is supported by resetting spring elements (8).

3. The display device according to claim 2, wherein the means for modifying the distance between the display (2) and the front pane (1) are bimetallic springs (4), which are respectively arranged around a profile (5) extending perpendicularly to the planes defined by the surfaces of the front pane (1) and of the display (2), the end of the profile (5) facing the front pane (1) being arranged in a fixed manner either on a support (6) of the front pane (1) or on a further structural component of the display device, the support (3) of the display (2) has on at least one side respectively at least two sliding members (7), which are respectively guided in an adjustable manner along a profile (5) and respectively arranged between the bimetallic spring (4) and a resetting spring (8), and the bimetallic spring (4) is respectively arranged between the sliding member (7) and the end of the profile (5) facing the front pane (1), and the resetting spring (8) is respectively arranged between the sliding member (7) and the end of the profile (5) facing away from the front pane (1).

4. The display device according to claim 2, wherein the means for modifying the distance between the display (2) and the front pane (1) are bimetallic springs (4), which are respectively arranged around a sliding pin (10) configured in the shape of a cylinder extending perpendicularly to the planes defined by the surfaces of the front pane (1) and of the display (2), the end of the pin (10) facing the front pane (1) being connected either to a support (6) of the front pane (1) or to a further structural component of the display device, the support (3) of the display (2) has on at least two opposite sides respectively at least one sliding sleeve (11), into which a sliding pin (10) is respectively guided, and the bimetallic springs (4) press against the support (6) of the front pane (1) or a further structural component and against the support (3) of the display (2) and, in the event of an increase in the temperature, move the support (3) of the display (2) against the force of respectively one resetting spring (8) in a direction away from the front pane (1).

5. The display device according to claim 2, wherein the means for modifying the distance between the display (2) and the front pane (1) comprise at least one bimetallic strip (15) connected at its ends to the front pane (1) or to a structural component connected to the front pane (1), the at least one bimetallic strip (15) abutting the support (3) of the display (2) or being connected to the support, bulging in the event of an increase of temperature in the direction of the display (2) and moving the latter against the force of the at least one resetting spring axially in a direction away from the front pane (1), and, in the event of a fall in temperature, the contraction process of the at least one bimetallic strip is supported by the at least one resetting spring.

6. The display device according to claim 2, wherein, as means for modifying the distance between the display (2) and the front pane (1), at least one arched bimetallic strip (15) is provided, whose one end is connected to the support (6) of the front pane (1) and whose other end is connected to the support (3) of the display (2), which expands in the event of an increase in the temperature and moves the display (2) axially in a direction away from the front pane (1).

7. The display device according to claim 2, wherein, as means for modifying the distance between the display (2) and the front pane (1), a bimetallic spring (4) or an arched bimetallic strip is provided centrally on the back of the display (2), and the bimetallic spring (4) or the bimetallic strip is connected by its end facing away from the display (2) to the support (3) of the display (2) or to a structural component connected to the support (3), while the other end facing the display (2) is connected to the structural component (23) arranged in a fixed manner in the display device, which is arranged between the display (2) and the support (3) of the display (2) or the structural component connected to the support, so that, in the event of an increase in the temperature, the distance between the display (2) and the front pane (1) is increased due to the expansion of the bimetallic spring (4) or bimetallic strip.

8. The display device according to claim 2, wherein, as means for modifying the distance between the front pane (1) and the display (2) as a function of the temperature, at least one electric, pneumatic, hydraulic or electromagnetic actuator is provided, which is controlled by a control unit as a function of the temperature determined by at least one sensor in order to set the predetermined distance between the display (2) and the front pane (1) as a function of the temperature.

9. The display device according to claim 8, wherein a proximity sensor is provided, and, if a presence of a person in front of the display device is detected by the sensor and the distance between the display (2) and the front pane (1) does not correspond to the minimum value, the at least one actuator is activated in order to reduce the distance between the front pane (1) and the display (2) to the minimum value so that an optimal readability and operability is guaranteed during the presence of the person, high temperatures notwithstanding.

10. The display device according to claim 1, wherein the support (3) of the display (2) is mounted by sliding pins (12), which are formed by the support (6) of the front pane (1) or are connected to said support (6), and sliding sleeves (13) formed by the support (3) of the display (2) or connected to said support (3), in which the sliding pins (12) are guided.

11. The display device according to claim 1, wherein the support (3) of the display (2) is mounted by plastic or rubber rollers (16) mounted in a rotatable manner on the support (3), which rollers (16) are guided in a guide rail (17) connected to the support (6) of the front pane (1) and respectively constitute a mounting unit (18), and at least two mounting units (18) are provided on at least two opposite sides of the display (2) and of the front pane (1).

12. The display device according to claim 1, wherein the support (3) of the display (2) is mounted via a spindle (19), which engages in a threaded bushing (20) connected to the support (3) of the display (2) and is attached to the support (6) of the front pane (1) via an axially fixed, yet radially freely rotatable ball bearing (21).

13. The display device according to claim 1, wherein the support (3) of the display (2) is mounted by means-of springs (25) provided in the support (3) of the display (2), and the springs (25) engaging in grooves (26) provided in the support (6) of the front pane (1).
